(19) United States
(12) Patent Application Publication
(10) Pub. No.: US 2007/0075430 A1
(43) Pub. Date: Apr. 5, 2007

(54) Solder joint intermetallic compounds with improved ductility and toughness

(76) Inventors: Daewoong Suh, Phoenix, AZ (US); Heeman Choe, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/241,190

(22) Filed: Sep. 30, 2005

(51) Int. Cl. H01L 23/48

(52) U.S. Cl. 257/762

(57) ABSTRACT

A method including forming a intermetallic compound including (1) an interfacial reaction product between a solder and a contact point and (2) a reaction species. A method including doping a solder material with a species; and forming a intermetallic compound including an interfacial reaction product between the solder material and a contact point. A system including a computing device including a microprocessor, the microprocessor coupled to a printed circuit board through a substrate, the substrate including a first set of contact points and a second set of contact points, wherein the microprocessor is coupled to the substrate through the first set of contact points, and the substrate is coupled to the printed circuit board through the second set of contact points, wherein at least one of the first set of contact points and the second set of contact points. Also a substrate.

### BACKGROUND

1. Field

Integrated circuit packaging.

2. Background

Integrated circuit chips or die are typically assembled into a package that is soldered to a printed circuit board. A chip or die may have contacts on one surface that are used to electrically connect the chip or die to a package substrate and correspondingly an integrated circuit to the package substrate. Accordingly, a suitable package substrate may have corresponding contacts on one surface. One way a number of contacts of a chip or die are connected to contacts of a package substrate are to a solder ball contacts in, for example, a controlled collapse chip connect (C4) process. The package substrate typically also has a number of contacts on an opposite surface that are used to electrically connect the package substrate to a printed circuit board. One way this may be done is through solder connections such as a ball grid arrays (BGAs).

Current industry practice is to replace traditional lead-based solder joints with lead-free solder joints. Lead-free solder joints typically have inferior shock performance relative to their leaded counterpart. As future packaging technology is driven towards finer pitch as package size shrinks and input/output (I/O) count increases, there is a concern that lead-free solder joints may not provide adequate shock performance in these applications (for example, less than 0.8 millimeters (mm) in pitch size for BGA applications).

### BRIEF DESCRIPTION OF THE DRAWINGS

Features, aspects, and advantages of embodiments will become more thoroughly apparent from the following detailed description, appended claims, and accompanying drawings in which:

FIG. 1 shows a package connected to a motherboard and a computer system.

FIG. 2 shows a single solder connection between contact point.

FIG. 3 shows a representation of a grain structure of an intermetallic compound and boron segregating to the grain boundaries.

### DETAILED DESCRIPTION

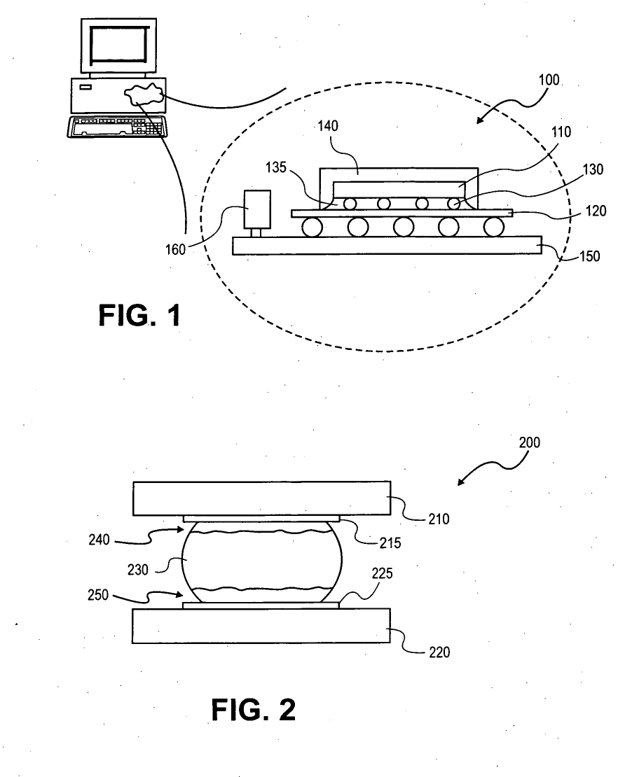

FIG. 1 shows an embodiment of an electronic assembly including a package connected to a printed circuit board (PCB). The electronic assembly may be part of an electronic system such as a computer (e.g., desktop, laptop, hand-held, server, internet appliance, etc.), a wireless communication device (e.g., cellular phone, cordless phone, pager), a computer-related peripheral (e.g., printer, scanner, monitor), and entertainment device (e.g., television, radio, stereo, tape player, compact disc player, video cassette recorder, Motion Picture Experts Group, audio writer 3 (MP3) player and the like. FIG. 1 shows electronic assembly 100 that is part of a desktop computer.

In the embodiment shown in FIG. 1, electronic assembly 100 includes chip or die 110, having a number of circuit devices formed thereon and therein, connected package substrate 120. Chip 110 is electrically connected to package substrate 120, in this embodiment, through lead-free solder connections 130 (shown as solder balls) between corresponding contact pads on chip 110 and package substrate 120, respectively. Disposed between chip 110 and package substrate 120 is underfill formulation 135 such as an epoxy. Disposed over chip 110 and package substrate 120 is molding compound 140 such as an epoxy.

FIG. 1 shows package substrate 120 connected to printed circuit board (PCB) 150. PCB 150 is, for example, a motherboard or other circuit board. Package substrate 120 is connected to PCB 150 through, for example, lead-free solder connections 155 at corresponding contact pads of package substrate 120 and PCB 150, respectively. PCB 150 may include other components, possibly connected to chip 110 through traces embedded in PCB 150. Representatively, FIG. 1 shows unit 160 that is, for example, a memory device, a power device or other device.

When lead-free solders (e.g., tin-silver-copper (Sn—Ag—Cu)) are melted on a metallic substrate, such as copper or nickel contact pads (e.g., contact points), in microelectronic packaging, the solders react with the substrate to form brittle intermetallic compounds (IMC) as a reaction product or interfacial layer that is part of the solder joints. Representatively, a lead-free solder for a BGA application is Sn—Ag—Cu (Ag is 0.3 to 0.4 wt. % and Cu is ˜0.5 wt. %) may be formed using 230 to 250 C as peak reflow temperature. Typical IMCs are Cu₆Sn₅ and/or Cu₃Sn for a copper substrate (copper contact pad or point) and Ni₃Sn₄ for a nickel substrate (contact pad or point) as well as Ag₃Sn IMCs that form in bulk solder.

FIG. 2 shows an example of a solder connection between substrates. FIG. 2 shows substrate 210 such as a package substrate including contact point 215. FIG. 2 also shows substrate 220, such as a printed circuit board including contact point 225. Solder connection 230 is disposed between and electrically connects contact point 215 and contact point 225. FIG. 2 also shows intermetallic compound (interfacial layers) 240 and intermetallic compound 250 formed after reflow of a reaction product between solder material and the contact point.

Under shock loading conditions, it is typically estimated that the strain rates that solder joints experience are of the order of 102 per second. This strain rate spans across dynamic and impact loadings. Under the strain rate, metallic materials exhibit so-called strain-rate sensitivity. In order words, metallic materials become stronger with increasing strain rate, according to the following relationship
σ=C(\dot{ε})^{m}|_{e,T}
wherein σ is flow stress,
C is a constant,
\dot{ε} is strain rate,
m is strain rate sensitivity, and
T is temperature.

The strain rate sensitivity is quite small at low homologous temperature but can be significant at high homologous temperatures to which solder materials are typically subjected during operation. For example, with m of 0.2, strain rate of 102/second increases yield strength to 250 percent of quasi-static yield strength. Because of this, under shock loading conditions, plastic deformation is generally suppressed and inherently ductile solder materials tend to become more and more brittle. Therefore, little or no plastic deformation is available to dissipate and/or absorb the incoming shock energy. With the shock energy transmitted to weaker intermetallic compound interfacial layers, solder joints typically exhibit a brittle fracture behavior along the IMC interfaces formed at joint regions under shock loading conditions.

In one embodiment, an intermetallic compound (IMC) is formed including an interfacial reaction product between (1) a solder material and a material of contact point and (2) a reaction species selected to improve the shock resistance of the IMC and a material of the contact point. In one embodiment, the reaction species is a Rare Earth element. Rare Earth elements tend to be extremely reactive. The chemical reactivity is believed due to the large negative-free energy from the formation of oxides/nitrides/hydrides. Due to their reactivity, Rare Earth elements will form an intermetallic compound with metals typically used in the metal finish of a contact point. In other words, a Rare Earth element will preferably form an intermetallic compound with copper, nickel, silver or gold rather than, for example, tin, after reflow. Rare Earth/contact metal IMCs have higher tensile ductility and fracture toughness than prior IMCs. The higher and fracture toughness will, in turn, mitigate brittle interfacial fracture during shock loading, resulting in improved shock performance and improved joint integrity/reliability. Thus, in one embodiment, a Rare Earth/contact metal IMC is formed with enough Rare Earth element(s) to increase the tensile ductility and fracture toughness of an IMC relative to an IMC formed without the Rare Earth element(s) present. A representative amount of Rare Earth element(s) is on the order of more than 0.1 weight percent to 10 weight percent of the IMC.

Suitable Rare Earth elements include Scandium (Sc), Yttrium (Y), Lanthanum (La), Cerium (Ce), Praseodymium (Pr), Neodymium (Nd), Promethium (Pm), Samarium (Sm), Europium (Eu), Gadolinium (Gd), Terbium (Th), Dysprosium (Dy), Holmium (Ho), Erbium (Er), Thullium (tm), Ytterbium (Yb), and Lutetium (Lu).

There are various ways of implementing various Rare Earth element(s) as an intermetallic compound. Rare Earth elements can be introduced (e.g., doped) into solder material, such as lead-free solder material using standard ingot metallurgy. For example, Rare Earth element(s) can be introduced (e.g., in elemental form) in an amount up to three weight percent. The melting of the ingots should be conducted in a vacuum to minimize Rare Earth oxidation during processing. The ingots may then be used to form solder balls or paste that may be used, for example, in an integrated circuit package environment, such as to connect a chip to a package substrate or the package (chip and package substrate) to a printed circuit board.

An alternative to introduce Rare Earth elements in an intermetallic compound is introducing Rare Earth element(s) into a solder paste. For example, Rare Earth elements as a powder can be combined with a solder powder and the combined powder may be used to form the paste. Alternatively, a Rare Earth element powder can be mixed with conventional solder powder and mechanically-alloyed to form an alloyed powder. During a reflow of the paste, the Rare Earth element will preferably react with metals of the contact point.

In another alternative, Rare Earth element(s) can be introduced into solder flux. For example, Rare Earth powder can be mixed with or mechanically-alloyed with conventional flux to produce a Rare Earth element-doped flux. The flux may be introduced on a contact point prior to the introduction of the solder balls or paste. During reflow, the Rare Earth element(s) present in the flux will react with metal of the contact point. In yet another alternative, the Rare Earth element(s) may be coated on the contact point prior to introducing a solder material or a solder flux.

In the above discussion, an intermetallic compound is described including a reaction product between a Rare Earth element and a metal of the contact point. In another embodiment, a method is described wherein a species is introduced or doped into a solder material and the intermetallic compound or IMC is formed as an interfacial reaction product between the solder material and a contact point. The species introduced to the solder material, rather than reacting with a metal of the solder or contact point, will instead be present in a non-reacted sense in the IMC to improve the tensile ductility of the intermetallic compound as the solder joint.

In one embodiment, a species that tends to improve the ductility and (impact) toughness of an intermetallic compound and a solder joint is boron. When a solder joint is doped with an appropriate amount of boron, the improvement in ductility and toughness may be due to a number of potential benefits. For example, boron tends to segregate to imperfect, high-energy region (grain boundaries and interfaces) to promote bonds with current element. This segregation results in an increase of cohesive strength since the previously “weaker” regions of grain boundaries and interfaces approach the strength of the bulk. It is believed the fracture mode can change from intergranular to transgranular.

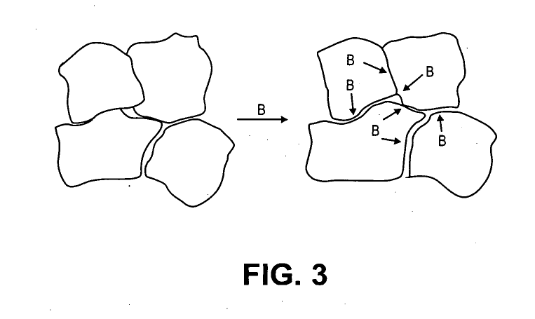

FIG. 3 shows a schematic illustration of metal grains formed in an intermetallic compound. FIG. 3 also shows that boron present in the solder material will tend to segregate to the grain boundaries to promote interatomic bond.

In addition to increasing the intrinsic toughness of grain boundaries and interfaces, boron may also limit environmental embrittlement. Moisture-induced hydrogen embrittlement of grain boundaries can occur in polycrystalline materials, such as Ni₃Al, Ni₄Mo, etc. Boron doping tends to minimize embrittlement for the suggested reason that boron atoms in grain boundaries inhibit the diffusion of hydrogen atoms due to a repulsive interaction between them. Boron doping may also improve the ductility and toughness of an intermetallic compound and a solder joint through grain size refinement. Boron doping is known to retard grain growth at elevated temperatures (e.g., during reflow or at high operating temperatures). In general, grain refinement results in strength enhancement and may lead to improved shock resistance of interfacial layers of intermetallic compound.

Boron may be introduced (doped) into solder material in various ways. For example, small amounts of boron, such as parts per million levels up to one weight percent, can be added into a solder ingot using conventional ingot metallurgical processes. In one embodiment, boron levels of one weight percent or less, are preferred as higher concentrations could result in the formation of borides that may be generate detrimental effects of mechanical properties. The boron-doped ingot is used as a starting material for a subsequent solder ball and powder processes using conventional procedures. Boron can, alternatively, be added to paste by adding a small of boron powder during powder mixing.

Boron may also be utilized in an electroless process. For example, in an electroless nickel deposit, a layer of nickel-phosphorous is typically introduced as a diffusion barrier. Boron may be substituted for phosphorous (e.g., to form a layer of nickel-boron) or as a surface finish on a layer of nickel-phosphorous.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. A method comprising:
forming a intermetallic compound comprising (1) an interfacial reaction product between a solder and a contact point and (2) a reaction species selected to improve the shock resistance of the intermetallic compound.

2. The method of claim 1, wherein the reaction species comprises a Rare Earth metal and the contact point.

3. The method of claim 1, wherein the contact point comprises a metal material selected from the group consisting of copper, silver, and gold.

4. The method of claim 1, wherein prior to forming the intermetallic coating, combining a precursor to the reaction species with a solder source.

5. The method of claim 4, wherein combining comprises coating the precursor on the solder source.

6. The method of claim 1, wherein prior to forming the intermetallic coating, the method comprises introducing a flux on the contact point, wherein the flux comprises the a precursor to the reaction species.

7. The method of claim 1, wherein prior to forming the intermetallic coating, the method comprises introducing the a precursor to the reaction species on the contact point.

8. A method comprising:
doping a solder material with a species; and
forming a intermetallic compound comprising an interfacial reaction product between the solder material and a contact point, wherein the species comprises a property that tends to segregate the species to grain boundaries of the intermetallic compound.

9. The method of claim 8, wherein the species comprises boron.

10. The method of claim 9, wherein doping the solder material with a species comprises doping the solder material with up to one weight percent of boron.

11. The method of claim 10, wherein the solder material comprises one of a solder ingot and a solder paste.

12. The method of claim 8, wherein the intermetallic compound is formed by an electroless process.

13. A system comprising:
a computing device comprising a microprocessor, the microprocessor coupled to a printed circuit board through a substrate, the substrate comprising a first set of contact points and a second set of contact points,
wherein the microprocessor is coupled to the substrate through the first set of contact points, and the substrate is coupled to the printed circuit board through the second set of contact points,
wherein at least one of the first set of contact points and the second set of contact points comprises an intermetallic compound comprising a reaction product between a solder and the contact point, the intermetallic compound comprising a species to improve the shock resistance of the intermetallic compound.

14. The system of claim 13, wherein the species comprises a reaction species comprising a Rare Earth metal and the contact point.

15. The system of claim 14, wherein the contact point comprises a metal material selected from the group consisting of copper, silver and gold.

16. The system of claim 13, wherein the species comprises a property having a tendency to segregate to grain boundaries of the intermetallic compound.

17. The system of claim 16, wherein the species comprises boron.

18. An apparatus comprising:
a substrate comprising a first set of contact points and a second set of contact points,
wherein at least one of the first set of contact points and the second set of contact points comprises an intermetallic compound comprising a reaction product between a solder and the contact point, the intermetallic compound comprising a species to improve the shock resistance of the intermetallic compound.

19. The system of claim 18, wherein the species comprises a reaction species comprising a Rare Earth metal and the contact point.

20. The system of claim 19, wherein the contact point comprises a metal material selected from the group consisting of copper, silver and gold.

21. The system of claim 18, wherein the species comprises a property having a tendency to segregate to grain boundaries of the intermetallic compound.

22. The system of claim 21, wherein the species comprises boron.
